(19) United States
(12) Patent Application Publication
(10) Pub. No.: US 2010/0120184 A1
(43) Pub. Date: May 13, 2010

(54) OPTOELECTRONIC DEVICE STRUCTURE

(76) Inventors: Chien-Fu HUANG, Hsinchu (TW); Chia-Liang Hsu, Hsinchu (TW)

Correspondence Address: Muncy, Geissler, Olds & Lowe, PLLC, P.O. BOX 1364, FAIRFAX, VA, 22038-1364, US

(21) Appl. No.: 12/617,413

(22) Filed: Nov. 12, 2009

(30) Foreign Application Priority Data
Nov. 13, 2008 (TW) 097144439

(51) Int. Cl. H01L 21/30

(52) U.S. Cl. 438/29; 257/E21.211

(57) ABSTRACT

The application is related to an optoelectronic device structure including a stress-balancing layer. The optoelectronic device structure comprises a high thermal conductive substrate, a stress-balancing layer on the high thermal conductive substrate, a reflective layer on the stress-balancing layer and an epitaxial structure on the reflective layer.

### CROSS REFERENCE TO RELATED APPLICATIONS

This application claims the right of priority based on Taiwan Patent Application No. 097144439 entitled “Optoelectronic Device Structure”, filed on Nov. 13, 2008, which is incorporated herein by reference and assigned to the assignee herein.

### TECHNICAL FIELD

The present application generally relates to an optoelectronic device structure and method for manufacturing thereof, and more particularly to a high thermal conductive light-emitting diode structure and method for manufacturing.

### BACKGROUND

Sapphire is commonly used as the substrate for supporting the blue light-emitting diode (LED) and is a low thermal conductive material (the coefficient of the thermal conductivity is about 40W/mK). It is difficult for sapphire to deliver the heat efficiently when the blue LED is operated under high current condition. Therefore, the heat is accumulated and the reliability of the blue LED is affected.

Copper with high coefficient of thermal conductivity (˜400W/mK) is later introduced to be the substrate of the LED by electro-plating or adhesion method so it can dissipate the heat efficiently. However, after removing the growth substrate, the internal stress compresses the whole piece of copper substrate and results in a warp in the wafer, and the reliability in the following processes is therefore influenced.

### SUMMARY

The present application is to provide an optoelectronic device structure containing a substrate which is high thermal conductive and can be made of copper, aluminum, molybdenum, silicon, germanium, metal matrix composite material, copper alloy, aluminum alloy, or molybdenum alloy.

The present application is to provide an optoelectronic device structure containing a substrate which is high thermal conductive and can be formed by electroless plating, electro-plating, and electroform.

The present application is to provide an optoelectronic device structure containing a stress-balancing layer of a single layer structure or multiple layers structure.

The present application is to provide an optoelectronic device structure wherein the material of the stress-balancing layer can be nickel, tungsten, molybdenum, cobalt, platinum, gold, or copper.

The present application is to provide an optoelectronic device structure wherein the stress-balancing layer can be formed by electroless plating, electro-plating, and electroform.

The present application is to provide an optoelectronic device structure containing a substrate that is high thermal conductive, and the difference between the thermal expansion coefficient of the high thermal conductive substrate and that of the stress-balancing layer is not smaller than 5 ppm/° C.

The present application is to provide an optoelectronic device structure wherein the thickness of the stress-balancing layer is not smaller than 0.01 time and not greater than 0.6 time that of the high thermal conductive substrate.

The present application is to provide an optoelectronic device structure wherein the stress-balancing layer has a regularly patterned structure.

The present application is to provide an optoelectronic device structure wherein the width of each pattern of the regularly patterned structure of the stress-balancing layer is not smaller than 0.01 time and not greater than 1 time that of the optoelectronic device.

The present application is to provide an optoelectronic device structure wherein the thickness of the stress-balancing layer with a regularly patterned structure is not smaller than 0.01 time and not greater than 1.5 times that of the high thermal conductive substrate.

The present application is to provide an optoelectronic device structure wherein the width of the stress-balancing layer is greater than that of the high thermal conductive substrate.

The present application is to provide an optoelectronic device structure wherein the material of the epitaxial structure including one or more elements selected from a group consisting of gallium, aluminum, indium, arsenic, phosphorous, and nitrogen.

### BRIEF DESCRIPTION OF THE DRAWINGS

The foregoing aspects and many of the attendant advantages of this application will become more readily appreciated as the same becomes better understood by reference to the following detailed description, when taken in conjunction with the accompanying drawings, wherein:

FIGS. 1-5 illustrate a process flow of forming an optoelectronic device in accordance with one embodiment of the present application;

FIGS. 6-9 illustrate a process flow of forming an optoelectronic device in accordance with another embodiment of the present application;

FIGS. 10-12 illustrate a process flow of forming an optoelectronic device in accordance with further another embodiment of the present application;

FIG. 13 illustrates a known light-emitting device structure.

### DETAILED DESCRIPTION OF THE PREFERRED EMBODIMENTS

The present application discloses an optoelectronic device structure with a stress-balancing layer and method for manufacturing thereof.

### The Embodiment 1

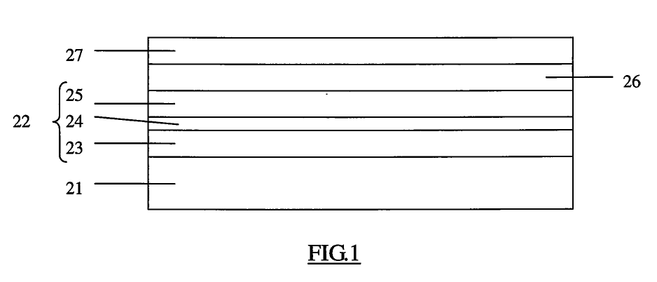

A light-emitting diode is described in the following to exemplify the embodiment of the optoelectronic device structure of the present application where the structure and the method for manufacturing thereof are shown in FIG. 1 to FIG. 5. Referring to FIG. 1, the structure includes a growth substrate 21, and the material of the growth substrate can be GaAs, Si, SiC, Sapphire, InP, Galn, AlN, or GaN. Then an epitaxial structure 22 is formed on the growth substrate 21. The epitaxial structure 22 is formed by the epitaxial process such as MOCVD, LPE, or MBE epitaxial process. The epitaxial structure 22 includes at least a first conductive type semiconductor layer 23, such as n-type (AlₓGa₁₋ₓ)_{y}In_{1-y}P layer or n-type (AlₓGa₁₋ₓ)_{y}In_{1-y}N layer; an active layer 24, such as a multiple quantum wells structure of (AlₐGa₁₋ₐ)_{b}In_{1-b}P or (AlₐGa₁₋ₐ)_{b}In_{1-b}N; and a second conductive type semiconductor layer 25, such as p-type (AlₓGa₁₋ₓ)_{y}In_{1-y}P layer or p-type (AlₓGa₁₋ₓ)_{y}In_{1-y}N layer. Besides, the active layer 24 in this embodiment can be formed as a homostructure, single heterostructure, or double heterostructure.

A second contact layer 26 and a reflective layer 27 are later formed on the epitaxial structure 22. The material of the second contact layer 26 can be indium tin oxide, indium oxide, tin oxide, cadmium tin oxide, zinc oxide, magnesium oxide, or titanium nitride. The material of the reflective layer 27 can be metal material such as silver, aluminum, titanium, chromium, platinum, or gold.

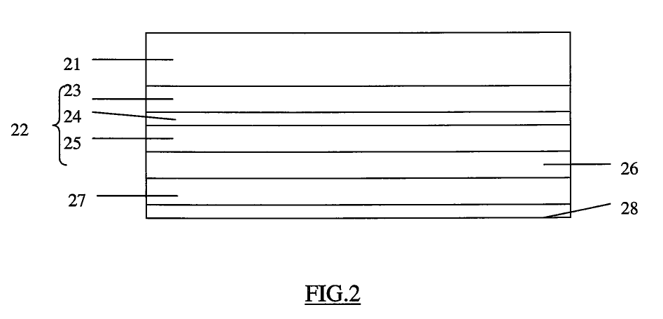

Next, the epitaxial structure with the reflective layer 27 is immersed in the chemical basin with the growth substrate 21 oriented up and the reflective layer 27 oriented down for the electro chemical deposition process such as electro-plating or electroform, or the electroless chemical deposition process such as electroless plating, and a stress-balancing layer 28 is formed under the reflective layer 27. The material of the stress-balancing layer can be nickel, tungsten, molybdenum, cobalt, platinum, gold, or copper. The structure is shown in FIG. 2. The stress-balancing layer can also be the reflective layer if its reflectivity is high enough so the reflective layer 27 can be omitted.

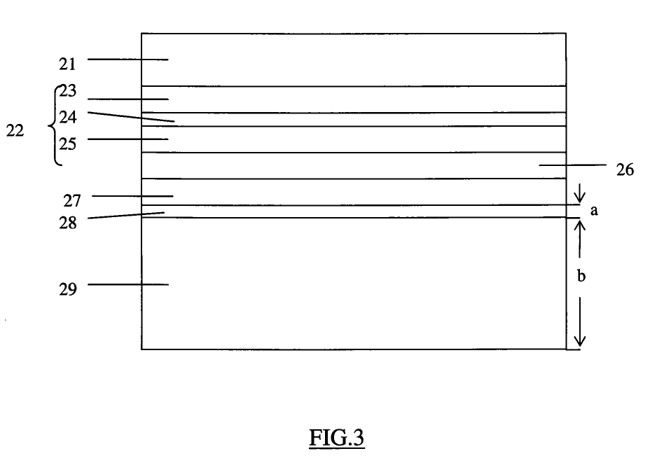

As the FIG. 3 shows, the structure with the stress-balancing layer 28 is immersed in another chemical basin for additional electro chemical deposition process such as electro-plating or electroform, or additional electroless chemical deposition process such as electroless plating to form a high thermal conductive substrate 29 under the stress-balancing layer 28, and a wafer structure is formed accordingly. The material of the high thermal conductive substrate can be copper, aluminum, molybdenum, silicon, germanium, tungsten, metal matrix composite material, copper alloy, aluminum alloy, or molybdenum alloy. The criterion for the material of the high thermal conductive substrate is that the difference between the thermal expansion coefficient of the substrate and that of the epitaxial structure is not smaller than 5 ppm/° C. In addition, the preferred thickness of the stress-balancing layer a is not smaller than 0.01 time the thickness of the high thermal conductive substrate b, and is not greater than 0.6 time that, i.e. 0.01b≦a≦0.6b.

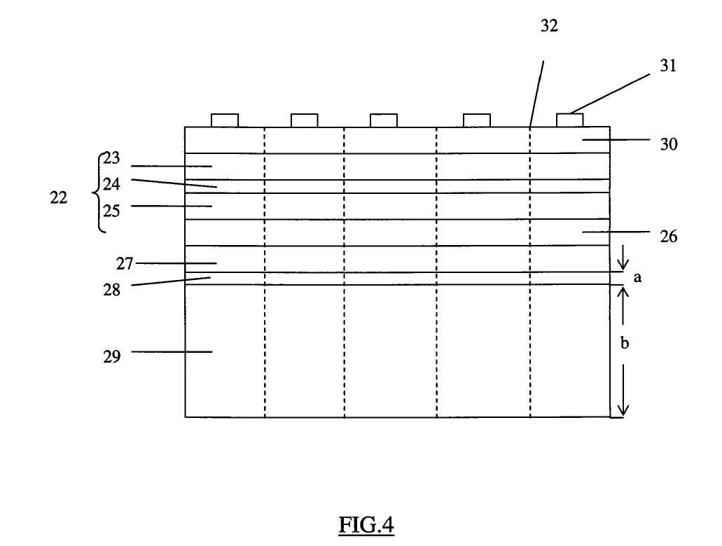

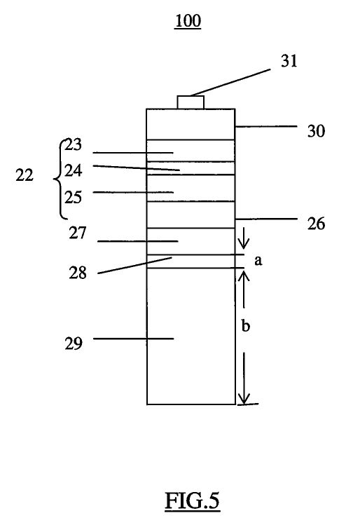

Next, as FIG. 4 shows, a portion of or the whole growth substrate 21 is removed by laser lift-off, etching or chemical mechanical polishing to expose the surface of the first conductive type semiconductor 23 of the epitaxial structure 22. Generally, after removing the growth substrate, the internal stress between the high thermal conductive substrate and the epitaxial structure can compress the whole high thermal conductive substrate and result in a warp in the wafer structure, and the reliability in the following processes is therefore influenced. By forming the stress-balancing layer, the internal stress between the high thermal conductive substrate and the epitaxial structure can be reduced, and the warp in the wafer structure can be suppressed. A first contact layer 30 is then formed on the exposed surface of the first conductive type semiconductor layer 23. The material of the first contact layer 30 can be a thin film made of indium tin oxide, indium oxide, tin oxide, cadmium tin oxide, zinc oxide, magnesium oxide, titanium nitride, Ge/Au, Ge/Au/Ni or Cr/Al. A pattern structure can be optionally formed on the thin film by etching process. A first electrode 31 is formed between the patterns of the pattern structure of the first contact layer 30 by the thermal evaporation, e-beam, or sputtering methods. If the first contact layer 30 is a continuous thin film without the pattern structure, the first electrode 31 can be formed directly on the first contact layer 30. The material of the first electrode can be Au—Zn alloy or Au—In alloy. In this embodiment, the high thermal conductive substrate 29 can also function as the second electrode. A plurality of dicing channels 32 is formed by etching, and the light-emitting diode chips 100 with a high thermal conductive substrate are formed after dicing along the dicing channels as FIG. 5 shows.

### The Embodiment 2

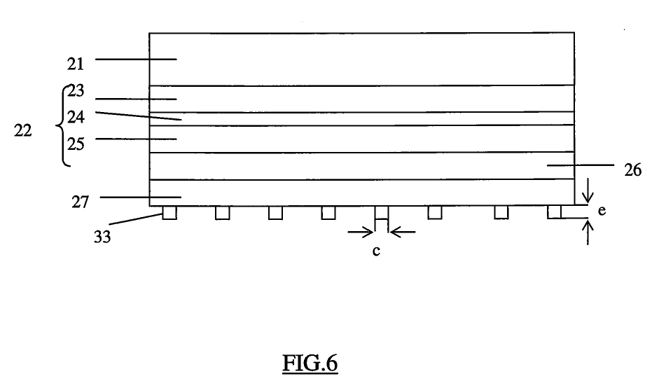

A light-emitting diode is described in the following to exemplify another embodiment of the optoelectronic device structure of the present application where the structure and the method for manufacturing thereof are shown in FIG. 1 and FIG. 6 to FIG. 9. The epitaxial structure is the same as the one shown in the FIG. 1 in the embodiment 1. Referring to FIG. 6, the epitaxial structure with the reflective layer 27 is immersed in the chemical basin with the growth substrate 21 oriented up and the reflective layer 27 oriented down for the electro chemical deposition process such as electro-plating or electroform, or the electroless chemical deposition process such as electroless plating, and a stress-balancing layer 33 is formed under the reflective layer. A stress-balancing layer with a regularly patterned structure is formed by the photolithography and etching process. The material of the stress-balancing layer can be nickel, tungsten, molybdenum, cobalt, platinum, gold, or copper. The stress-balancing layer can also be the reflective layer if its reflectivity is high enough so the reflective layer 27 can be omitted.

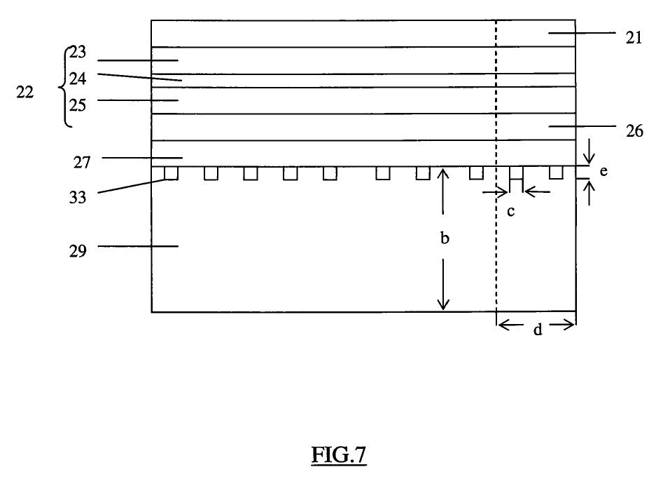

Referring to the FIG. 7, the stress-balancing layer 33 with a regularly patterned structure is immersed in another chemical basin for additional electro chemical deposition process such as electro-plating or electroform, or additional electroless chemical deposition process such as electroless plating to form a high thermal conductive substrate 29 in the interval of the regularly patterned structure of the stress-balancing layer and under the stress-balancing layer, so a wafer structure is formed. The material of the high thermal conductive substrate can be copper, aluminum, molybdenum, silicon, germanium, tungsten, metal matrix composite material, copper alloy, aluminum alloy, or molybdenum alloy. The width of the pattern of the regularly patterned structure of the stress-balancing layer c is not smaller than 0.01 time and not greater than 1 time that of the high thermal conductivity optoelectronic device d, i.e. 0.01d≦c≦d. The preferred thickness of the stress-balancing layer with regularly patterned structure e is not smaller than 0.01 time and not greater than 1.5 times that of the high thermal conductivity substrate b, i.e. 0.01b≦e≦1.5b.

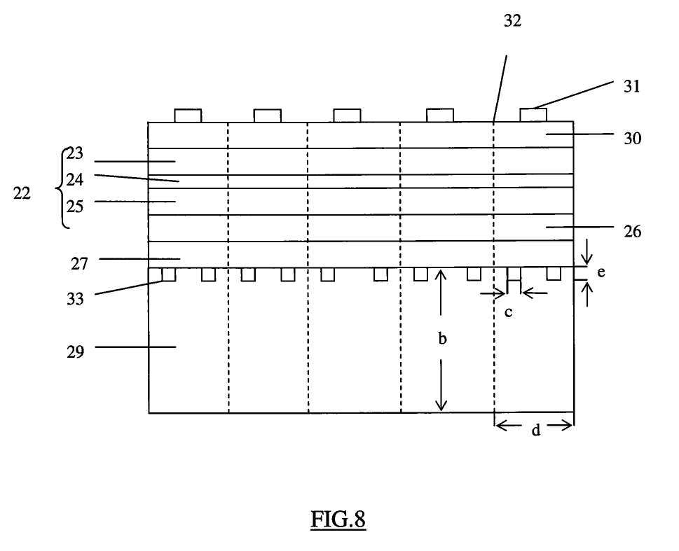

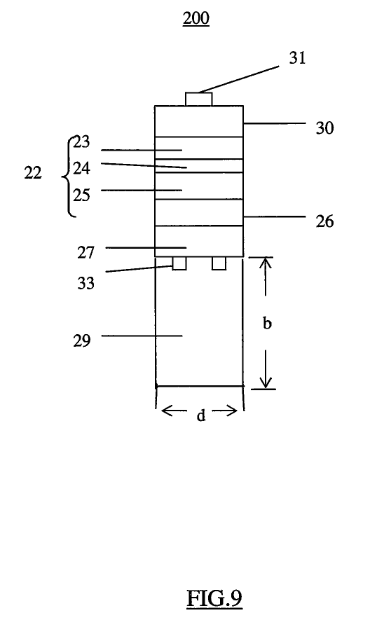

Next, as FIG. 8 shows, a portion of or a whole growth substrate 21 is removed by laser lift-off, etching or chemical mechanical polishing to expose the surface of the first conductive type semiconductor layer 23 of the epitaxial structure 22, then a first contact layer 30 is formed on the exposed surface of the first conductive type semiconductor layer 23. The material of the first contact layer 30 can be a thin film made of indium tin oxide, indium oxide, tin oxide, cadmium tin oxide, zinc oxide, magnesium oxide, titanium nitride, Ge/Au, Ge/Au/Ni, or Cr/Al. A pattern can be optionally formed on the thin film by etching process. The first electrode 31 is formed on the surface of the first contact layer 30. In this embodiment, the high thermal conductive substrate 29 can function as the second electrode. The material of the first electrode can be Au—Zn alloy or Au—In alloy. In this embodiment, a rough surface can also be formed on the upper surface or the lower surface of the first contact layer 30. A plurality of dicing channels 32 is formed by etching, and the light-emitting diode chips 200 with a high thermal conductive substrate are formed after dicing along the dicing channels as FIG. 9 shows.

### The Embodiment 3

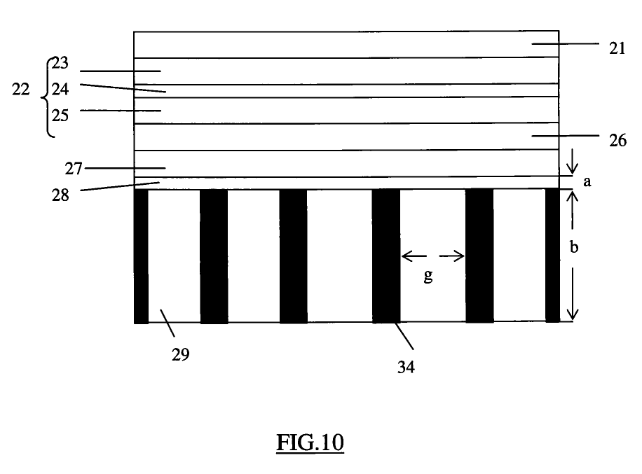

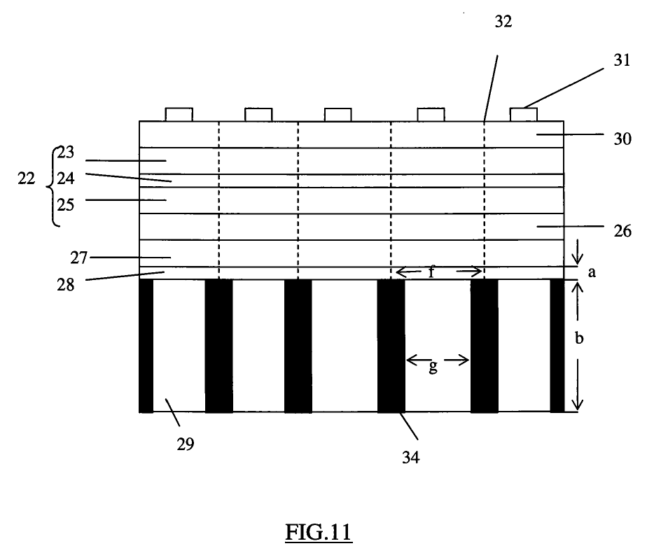

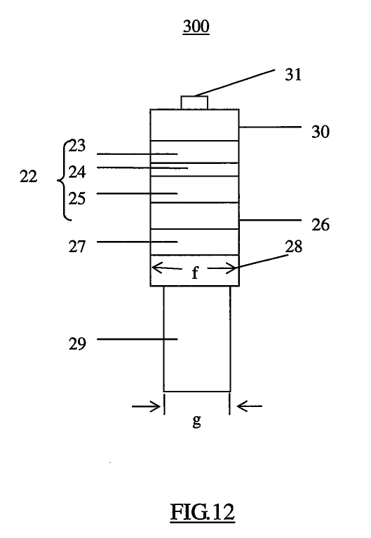

A light-emitting diode is described in the following to exemplify further another embodiment optoelectronic device structure of the present application where the structure and the method for manufacturing thereof as shown in FIGS. 1-2, and FIGS. 10-12. The epitaxial structure is the same as shown in FIGS. 1-2 in the embodiment 1. Referring to FIG. 10, a photoresist structure 34 with a plurality of intervals with a distance g is formed under the stress-balancing layer 28, then the structure is immersed in another chemical basin for additional electro chemical deposition process such as electro-plating or electroform, or additional electroless chemical deposition process such as electroless plating to form a high thermal conductive substrate 29 between the photoresist structure under the stress-balancing layer 28. A wafer structure is formed accordingly. The material of the high thermal conductive substrate can be copper, aluminum, molybdenum, silicon, germanium, tungsten, metal matrix composite material, copper alloy, aluminum alloy, or molybdenum alloy. Referring to FIG. 11, a portion of or a whole growth substrate 21 is removed by laser lift-off, etching or chemical mechanical polishing to expose the surface of the first conductive type semiconductor layer 23 of the epitaxial structure 22, then the first contact layer 30 is formed on the exposed surface of the first conductive type semiconductor layer 23. The material of the first contact layer 30 can be a thin film made of indium tin oxide, indium oxide, tin oxide, cadmium tin oxide, zinc oxide, magnesium oxide, titanium nitride, Ge/Au, Ge/Au/Ni, or Cr/Al. A pattern structure can be optionally formed by etching process. The first electrode 31 is formed between the patterns of the pattern structure of the first contact layer 30 by thermal evaporation, e-beam, or sputtering. If the first contact layer 30 is a continuous thin film without the pattern structure, the first electrode 31 can be formed directly on the first contact layer 30. The material of the first electrode can be Au—Zn alloy or Au—In alloy. In this embodiment, the high thermal conductive substrate 29 can function as the second electrode. A plurality of dicing channels 32 is formed by etching, and the light-emitting diode chips 300 with a high thermal conductive substrate are formed by dicing along the dicing channels as FIG. 12 shows. The difference between this embodiment and other embodiments is that the width of the high thermal conductive substrate 29 g is smaller than that of the stress-balancing layer 28 f, i.e. g<f. The larger the width of the high thermal conductive substrate, the larger the expansion internal stress. Even so, the high thermal conductive substrate 29 still needs sufficient width to deliver the heat, so it is better for the high thermal conductive substrate to have a width g smaller than that of the stress-balancing layer f.

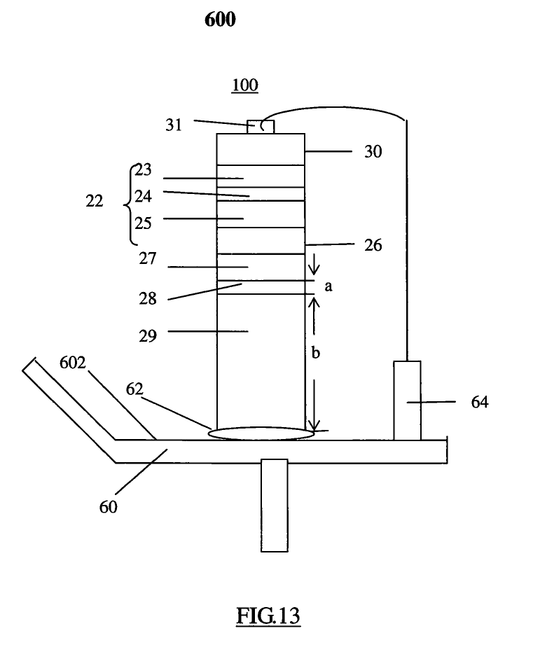

Beside, the light-emitting diode chips 100-300 described in the embodiments 1 to 3 can further combine with other devices to form a light-emitting apparatus. FIG. 13 is a diagram showing a light-emitting apparatus 600 including at least a submount 60 with a circuit 602 and a solder 62 on the submount 60. The above-mentioned light-emitting diode chip 100 is adhered on the submount 60, and the substrate 29 of the light-emitting diode chip 100 is connected electrically with the circuit 602 of the submount 60 by the solder 62. Furthermore, an electrical connecting structure 64 is electrically connected the electrode 31 of the light-emitting diode chip 100 with the circuit 602 on the submount 60. The submount 60 can be a lead frame or mounting substrate convenient for the circuit design of the light-emitting apparatus and the heat dispersion.

Although specific embodiments have been illustrated and described, it will be apparent that various modifications may fall within the scope of the appended claims.

We claim:

1. A method for forming an optoelectronic device comprising the steps of:
providing a growth substrate having a first surface and a second surface;
forming an epitaxial structure on the first surface of the growth substrate wherein the epitaxial structure comprising an n-type semiconductor layer, an active layer, and a p-type semiconductor layer;
forming a reflective layer on the epitaxial structure;
forming a stress-balancing layer by an electro chemical deposition process or an electroless chemical deposition process on a side of the reflective layer opposite to the epitaxial structure;
forming a high thermal conductive substrate by an electro chemical deposition process or an electroless chemical deposition process on a side of the stress-balancing layer opposite to the epitaxial structure wherein the stress-balancing layer can reduce the internal stress between the high thermal conductive substrate and the epitaxial structure, and the difference of the thermal expansion coefficients between the high thermal conductive substrate and the epitaxial structure is not smaller than 5 ppm/° C.;
removing the growth substrate to expose a surface of the epitaxial structure;
forming an electrode on the exposed surface of the epitaxial structure wherein the electrode electrically connected to the epitaxial structure;
forming a plurality of channels by etching from the epitaxial structure to the high thermal conductive substrate; and
dicing along the plurality of channels.

2. The method according to claim 1, wherein the electro chemical deposition process for forming the stress-balancing layer is electro-plating or electroform.

3. The method according to claim 1, wherein the electroless chemical deposition process for forming the stress-balancing layer is electroless plating.

4. The method according to claim 1, wherein the electro chemical deposition process for forming the high thermal conductive substrate is electro-plating or electroform.

5. The method according to claim 1, wherein the electroless chemical deposition process for forming the high thermal conductive substrate is electroless plating.

6. The method according to claim 1, wherein the step for forming the plurality of channels further comprising photolithography process.

7. A method for forming an optoelectronic device comprising the steps of:
providing a growth substrate having a first surface and a second surface;
forming an epitaxial structure on the first surface of the growth substrate wherein the epitaxial structure comprising an n-type semiconductor layer, an active layer, and a p-type semiconductor layer;
forming a reflective layer on the epitaxial structure;
forming a stress-balancing layer by an electro chemical deposition process or an electroless chemical deposition process on a side of the reflective layer opposite to the epitaxial structure;
forming a regularly patterned structure on the stress-balancing layer by etching process wherein the width of each pattern of the regularly patterned structure of the stress-balancing layer is not smaller than 0.01 time and not greater than 1 time that of the optoelectronic device;
forming a high thermal conductive substrate by an electro chemical deposition process or an electroless chemical deposition process on a side of the stress-balancing layer opposite to the epitaxial structure wherein the stress-balancing layer with a regularly patterned structure can reduce the internal stress between the high thermal conductive substrate and the epitaxial structure;
removing the growth substrate to expose a surface of the epitaxial structure;
forming an electrode on the exposed surface of the epitaxial structure wherein the electrode electrically connected to the epitaxial structure;
forming a plurality of channels by etching from the epitaxial structure to the high thermal conductive substrate; and
dicing along the plurality of channels.

8. The method according to claim 7, wherein the electro chemical deposition process for forming the stress-balancing layer is electro-plating or electroform.

9. The method according to claim 7, wherein the electroless chemical deposition process for forming the stress-balancing layer is electroless plating.

10. The method according to claim 7, wherein the electro chemical deposition process for forming the high thermal conductive substrate is electro-plating or electroform.

11. The method according to claim 7, wherein the electroless chemical deposition process for forming the high thermal conductive substrate is electroless plating.

12. The method according to claim 7, wherein the step for forming the plurality of channels further comprising photolithography process.

13. A method for forming an optoelectronic device comprising the steps of:
providing a growth substrate having a first surface and a second surface;
forming an epitaxial structure on the first surface of the growth substrate wherein the epitaxial structure comprising an n-type semiconductor layer, an active layer, and a p-type semiconductor layer;
forming a reflective layer on the epitaxial structure;
forming a stress-balancing layer by an electro chemical deposition process or an electroless chemical deposition process on a side of the reflective layer opposite to the epitaxial structure;
forming a photoresist structure with a plurality of intervals under the stress-balancing layer;
forming a high thermal conductive substrate by an electro chemical deposition process or an electroless chemical deposition process between the photoresist structure under the stress-balancing layer, wherein the width of the high thermal conductive substrate is smaller than that of stress-balancing layer, and the stress-balancing layer can reduce the internal stress between the high thermal conductive substrate and the epitaxial structure;
removing the photoresist structure under the stress-balancing layer;
removing the growth substrate to expose a surface of the epitaxial structure;
forming an electrode on the exposed surface of the epitaxial structure, wherein the electrode electrically connected to the epitaxial structure;
forming a plurality of channels by etching from the epitaxial structure to the high thermal conductive substrate; and
dicing the plurality of channels.

14. The method according to claim 13, wherein the electro chemical deposition process for forming the stress-balancing layer is electro-plating or electroform.

15. The method according to claim 13, wherein the electroless chemical deposition process for forming the stress-balancing layer is electroless plating.

16. The method according to claim 13, wherein the electro chemical deposition process for forming the high thermal conductive substrate is electro-plating or electroform.

17. The method according to claim 13, wherein the electroless chemical deposition process for forming the high thermal conductive substrate is electroless plating.

18. The method according to claim 13, wherein the step for forming the plurality of channels further comprising photolithography process.
